(19) United States
(12) Patent Application Publication
(10) Pub. No.: US 2012/0286772 A1
(43) Pub. Date: Nov. 15, 2012

(54) Metallic Pipeline Current Reader and Third Party Strike Damage Detector

(76) Inventors: Mark John Byerley, SR., Chino, CA (US); Roman Rafailovich Chak, North Hollywood, CA (US); Peter Lowe Harkins, Glendale, CA (US)

(21) Appl. No.: 13/103,579

(22) Filed: May 9, 2011

(51) Int. Cl. G01R 1/20

(52) U.S. Cl. 324/144

(57) ABSTRACT

This invention relates to the pipeline corrosion prevention and third party strike pipeline damage. The detector comprises of dual axis Anisotropic Magnetoresistive (AMR) magnetic sensor, analog signal conditional circuitry, digital circuitry, and a display. A pipe current magnitude and direction is measured via magnetic field surrounding the pipe. Magnetic field is sensed by the Anisotropic Magnetoresistive (AMR) magnetic sensor. The sensor converts magnetic field values into an electrical potential difference. This potential difference is converted into digital data and displayed on either computer screen or an LCD display. The current reader will be installed on a pipe and take continuous magnetic field reads (amplitude and direction).

Third party strike damage is detected by monitoring magnetic fields around a pipe and comparing them to a baseline magnetic field. Any mechanical damage on a pipe will distort baseline magnetic field value around the pipeline. This change will be detected by the sensor and transmitted to a user terminal.

### BACKGROUND OF THE INVENTION

The present invention relates to the pipeline corrosion prevention and third party strike pipeline damage. Corrosion is the degradation of a material through environmental interaction. Corrosion of most metals at near-ambient temperatures occurs in aqueous (water-containing) environments and is electrochemical in nature. Corrosion process can be detected by measuring voltages and currents present on a pipeline.

The proposed sensor is installed on above ground or underground pipes. Reference is now made to FIG. 2. Underground sensor installation:

1. Pipeline current reader and third party strike damage detector.

2. Ground level

3. Above ground test station

4. Pipe

Reference is now made to FIG. 3. Above ground installation:

1. Pipeline current reader and third party strike damage detector.

2. Ground level

3. Pipe

Pipeline current reader and third party strike damage detector transforms magnetic field energy into an electric potential difference. The electric potential difference is mathematically converted to current flow magnitude. Anisotropic Magneto-Resistive (AMR) sensors are simple resistive Wheatstone bridges that used to measure magnetic fields. With power supply applied to the bridges, the sensors convert any incident magnetic field in the sensitive axis directions to a differential voltage outputs. The magneto resistive sensors are made of a nickel-iron (Permalloy) thin-film deposited on a silicon wafer and patterned as a resistive strip element. In the presence of a magnetic field, a change in the bridge resistive elements causes a corresponding change in voltage across the bridge outputs. This differential voltage is converted into a single ended voltage output. The DC voltage offset circuit provides a constant DC offset to compensate for negative output differential voltage from AMR sensor. Low pass filter filters out transient noise spikes and reduces white noise bandwidth.

### FIGURE DESCRIPTIONS

FIG. 1 Amperes Law

FIG. 2 is an example of an underground sensor installation.

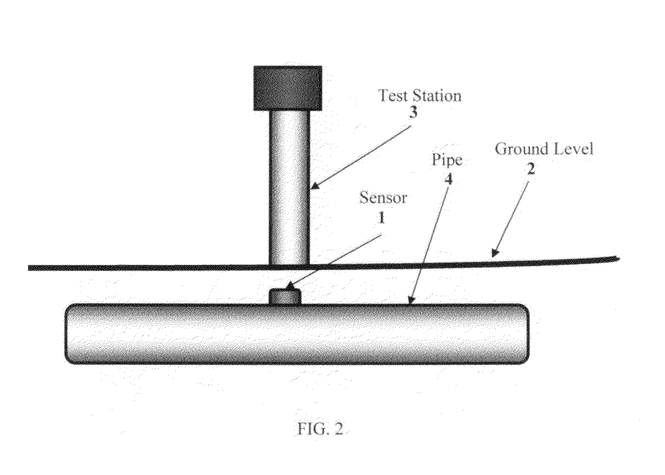

FIG. 3 is an example of an above ground sensor installation.

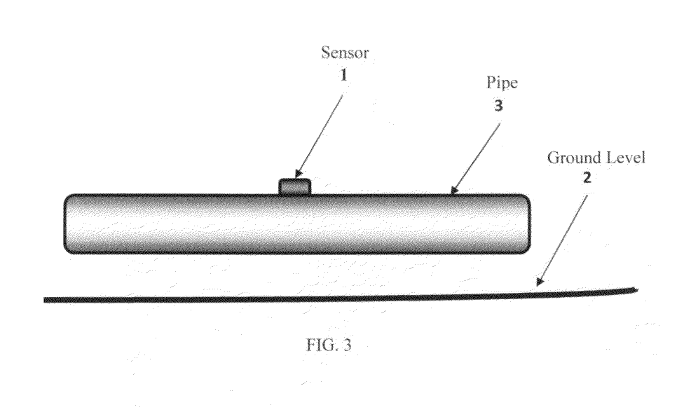

FIG. 4 shows AMR and analog input circuitry.

FIG. 5 shows an analog to A/D conditioning circuit.

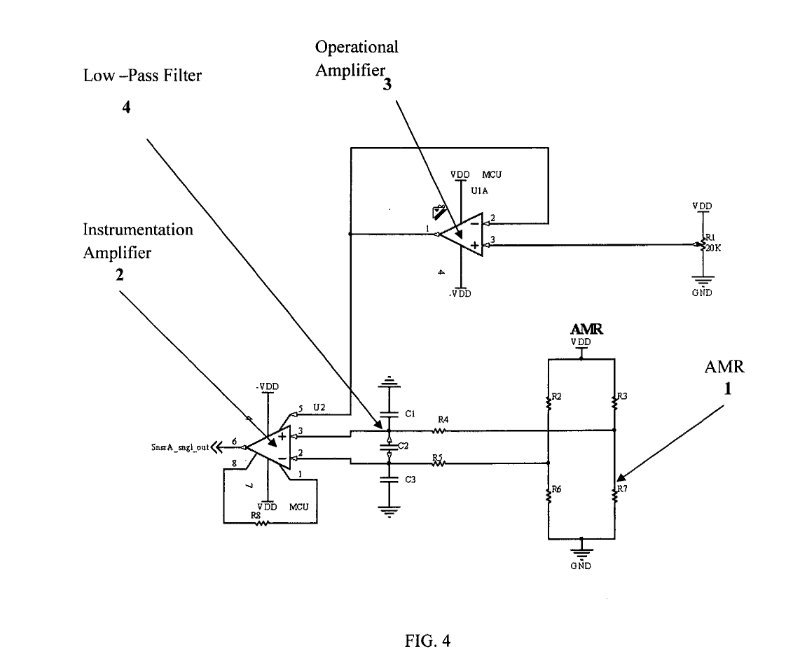

Reference is now made to FIG. 4. The input sensing circuit consist of:

1. Dual axis Anisotropic Magneto-resistive (AMR) (only one axis shown)

2. Differential amplifier circuit.

3. DC voltage offset circuit.

4. Low pass filter circuit.

Dual axis Anisotropic Magneto-resistive (AMR) registers ambient magnetic field. The resistance of the four magnetic resistor changes in response to a change in magnetic field. Since magnetic resistors are connected in a Wheatstone bridge pattern, the output differential voltage will also change. The Differential amplifier circuit amplifier circuit converts the differential output voltage to a single ended one. DC offset circuit is used to shift voltage readings into positive voltage range. Low pass filter is used to filter out random noise.

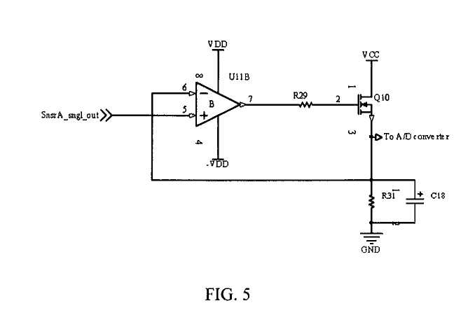

Reference is now made to FIG.5. Analog to digital (ADC) linear interface circuit is designed to interface analog circuitry to an analog to digital converter. This circuit has a linear 1:1 transfer function when input signal is between 0 and 3.3V. Above and below this range the signal will be clipped off. Maximum resolution of an ADC converter is achieved when dynamic range of analog signal is equal to VREF_MAX−VREF_MIN of an ADC converter. Analog to digital converter has VREF_MIN=0V and VREF_MAX=3.3V. Analog signal is applied to non-inverting input of the operational amplifier. Output signal is routed to an analog to digital converter. The single ended analog output voltage is digitized by an A/D converter. The result is displayed in Amperes.

The device herein described will be used to determine conditions of an underground or an above ground pipe or a pipeline.

Mark J. Byerley, Sr. (San Bernardino, Calif.)

Roman R. Chak (San Bernardino, Calif.)

Peter L. Harkins (San Bernardino, Calif.)

The invention claimed is:

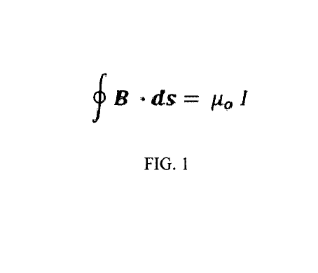

1. Pipeline current reader and third party strike damage detector will read and display current magnitudes and directions flowing on a pipe. The current will be measured via surrounding magnetic field and displayed in units of amperes, mille amperes, and micro amperes. Current direction and magnitude on a pipe relates to the surrounding magnetic field by Amperes Law (FIG. 1).

2. In the FIG. 1 equation B is the magnetic field, ds is a small length element, μ₀ is the magnetic permeability, and I is the pipe current.

3. The direction of the current will be displayed as a sign of current magnitude. Pipeline current reader and third party strike damage detector will detect third party strike damage by monitoring surrounding magnetic fields and comparing these reading to the baseline magnetic field.
